(19) United States
(12) Patent Application Publication
(10) Pub. No.: US 2011/0260325 A1
(43) Pub. Date: Oct. 27, 2011

(54) SEMICONDUCTOR DEVICE

(75) Inventor: Makoto Koto, Yokohama-shi (JP)

(73) Assignee: CANON KABUSHIKI KAISHA, Tokyo (JP)

(21) Appl. No.: 13/093,721

(22) Filed: Apr. 25, 2011

(30) Foreign Application Priority Data
Apr. 27, 2010 (JP) 2010-102693

(51) Int. Cl. H01L 23/48; B82Y 99/00

(52) U.S. Cl. 257/769; 977/762; 257/E23.01

(57) ABSTRACT

To provide a semiconductor device including vertically formed nanowires in which parasitic capacitance is prevented from increasing and time constant associated with an operation speed is improved. Two different layers, which are a film thickness adjustment layer and a protective insulating layer, are provided as an interlayer insulating film between an electrode and a planar main surface of an electrically conductive substrate. This structural characteristic can reduce parasitic capacitance generated among the nanowires which electrically connect the planar main surface and the electrode to each other, the electrically conductive substrate, and the electrode, while controlling peel-off of a low dielectric film having a poor adhesion by separating the low dielectric film from the electrode with the protective insulating layer interposed therebetween.

### BACKGROUND OF THE INVENTION

1. Field of the Invention

The present invention relates to a semiconductor device, more particularly to a semiconductor device provided with nanowires in which inter-wiring parasitic capacitance is reduced.

2. Description of the Related Art

The advancement of the semiconductor processing technique in the past years successfully led to an ongoing reduction of processing dimensions in metal-oxide-semiconductor (MOS) transistors, which greatly contributed to highly integrated semiconductor devices available today. However, the conventional planar scaling method often fails to accomplish expected characteristics, and such an adverse factor as a short-channel effect is becoming apparent with the reduction of feature size. Such current circumstances now demand some breakthrough other than just simple dimensional reduction.

Of the associated techniques currently developing, a vertical semiconductor device, which is advantageous in that planar cell size and gate length can be separately regulated, is a highly prospective technique expected to further drive the pursuit of higher integration in the future.

The vertical gate, fin gate, and surround gate are also attracting attention as potentially promising techniques for cell size reduction and better characteristics. While these techniques are becoming available, unidimensional semiconductor nanowire is also an attractive technique in anticipation of the production of transistors with good transmission characteristics, and the integration technique aided with the surround gate structure and vertical structure.

The nanowire can be produced by, for example, the top-down approach which employs lithography and etching, or bottom-up approach typified by vapor phase-liquid phase-solid phase (VLS). The bottom-up approach, though it can produce a circular monocrystal semiconductor nanowire in the dimension of at most a few hundred nm with a low crystal defect density, has not been applied to practical use in view of difficulties in growth orientation control and position control.

According to a production process conventionally adopted when silicon semiconductor nanowires obtained by VLS growth are used in a device, a stimulus, such as an ultrasonic wave, is applied to the grown nanowires so that the nanowires are separated from a substrate and then collected, and the collected nanowires are horizontally laid on another substrate to form electrodes on both ends thereof. According to the production process where the nanowires are horizontally and randomly laid on the substrate surface, however, it may be difficult to achieve the level of production from the viewpoint of reproducibiliy.

Japanese Patent Application Laid-Open (Translations of PCT application) No. 2008-503081 and “Small” 2, 85, 2006 discuss a solution for the technical difficulty, where VLS-grown nanowires perpendicular to a substrate are used in a device. In the device structures discussed in these documents, upper and lower ends of the nanowires vertically extending are connected to the substrate and upper electrodes.

The conventional structures discussed in these documents, in which the substrate having a large area is connected to one ends of the nanowires, involve a concern for increase of parasitic capacitance thought to be generated between the electrodes on both ends. Another concern is increase of gate-source and gate-drain parasitic capacitances thought to be generated in, for example, a vertical field-effect transistor device provided with nanowires serving as a channel due to its three-dimensional shape.

### SUMMARY OF THE INVENTION

The present invention is directed to a semiconductor device in which parasitic capacitance is reduced.

According to an aspect of the present invention, a semiconductor device having a multilayered structure where multiple layers are stacked on a planar main surface of an electrically conductive substrate in the order of a film thickness adjustment layer, a protective insulating layer, and an electrode, wherein nanowires penetrate through the film thickness adjustment layer and the protective insulating layer to electrically connect the electrically conductive substrate and the electrode to each other.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 is a schematic diagram illustrating a semiconductor device according to an exemplary embodiment of the present invention.

FIGS. 2A to 2H illustrate steps of a production process for producing the semiconductor device according to an exemplary embodiment of the present invention.

### DESCRIPTION OF THE EMBODIMENTS

Various exemplary embodiments, features, and aspects of the invention will be described in detail below with reference to the drawings.

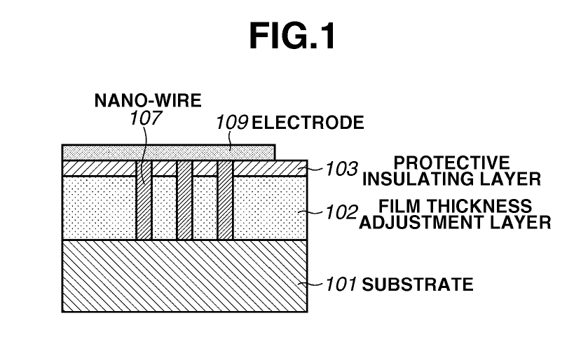

FIG. 1 is a schematic diagram illustrating a semiconductor device according to an exemplary embodiment of the present invention. Referring to FIG. 1, a semiconductor device according to the present exemplary embodiment has a multilayered structure where multiple layers are stacked on a planar main surface of an electrically conductive substrate 101 in the order of a film thickness adjustment layer 102, a protective insulating layer 103, and an electrode 109. The multilayered structure is further provided with nanowires 107 each including a semiconductor. The nanowires 107 penetrate through the film thickness adjustment layer 102 and the protective insulating layer 103 to electrically connect the electrically conductive substrate 101 and the electrode 109 to each other.

Thus, the semiconductor device according to the present exemplary embodiment is structurally characterized in that two interlayer insulating films, which are the film thickness adjustment layer 102 and the protective insulating layer 103, are provided between the planar main surface of the electrically conductive substrate 101 and the electrode 109. According to the structure, the film thickness adjustment layer 102 having a low dielectric constant is separated from the electrode 109 with the protective insulating layer 103 interposed therebetween so that the film thickness adjustment layer 102 is prevented from peeling off. Another advantage of the structure is to reduce parasitic capacitance among the nanowires 107 which provide electrical connection between the planar main surface of the electrically conductive substrate 101 and the electrode 109, the electrically conductive substrate 101, and the electrode 109.

The nanowires may be formed substantially perpendicular to the planar surface of the electrically conductive substrate.

The nanowires each may have a diameter in the range of at least 1 nm to at most 200 nm.

The nanowires may contain one of a Group IV device, a compound including a Group III element and a Group V element, and a compound including a Group II element and a Group VI element by at least 90% by weight. The Group IV element may be Si, Ge or Si, Ge, C.

The compound including the Group III element and the Group V element may be a compound in which one of Ga, Al, and In of the Group III element is included or at least two of these elements are combined, and N, P, As, Sb, or Bi is included as the Group V element.

The compound including the Group II element and the Group VI element maybe a compound in which Zn or Cd is included as the Group II element and O, Se, or Te is included as the Group VI element. The protective insulating layer may have Young's modulus equal to or larger than 100 GPa.

The electrode may be formed from metal, a semiconductor doped with an impurity, or silicide. The impurity may include any of B, P, and As. The silicide may include a combination of Si and any of Ti, Zr, Hf, V, Nb, Ta, Cr, W, Mn, Tc, Re, Fe, Ru, Os, Co, Rh, Ir, Ni, Pd, Pt, and Al.

The semiconductor device according to the exemplary embodiment of the present invention is described referring to FIG. 1.

The semiconductor device according to the present exemplary embodiment includes an electrically conductive substrate 101 which defines a planar main surface, a film thickness adjustment layer 102 formed on the planar main surface, a protective insulating layer 103 formed on the film thickness adjustment layer 102, an electrode 109 formed on the protective insulating layer 103, and nanowires 107 each including a semiconductor and penetrating through the film thickness adjustment layer 102 and the protective insulating layer 103 substantially perpendicular to the planar main surface in a region where the protective insulating layer 103 is removed so that the electrode and the electrically conductive substrate are electrically insulated from each other.

The semiconductor device according to the present exemplary embodiment is provided with the nanowires each including the semiconductor and penetrating through the film thickness adjustment layer and the protective insulating layer to electrically connect the electrode and the electrically conductive substrate to each other. The semiconductor device according to the present exemplary embodiment is a vertical semiconductor device advantageous in that deterioration of an operation speed is less likely, wherein the electrically conductive substrate and the electrode are insulated from each other with the film thickness adjustment layer having a low dielectric constant interposed therebetween, and the film thickness adjustment layer having a low dielectric constant is coated with the protective insulating layer. The semiconductor device thus structurally characterized can reduce inter-wiring parasitic capacitances without undermining adhesion and processability of upper wirings, thereby more effectively preventing the operation speed from slowing down.

A conventional material of the substrate 101 is silicon. Another example of the material of the substrate 101 is a semiconductor material in which the growth orientation of the nanowires can be controlled using the planar dependency of a surface potential when the nanowires are formed as described below, an example of which is a Ge substrate.

In the perspective of using the nanowires as an electrically conductive device, the substrate may include, in at least their contact points with the nanowires, a p-type impurity such as B or an n-type impurity such as Pin the volume of at least approximately 10¹⁷ per one cubic centimeter.

A silicon oxide film, or an oxide insulating film such as a Tetra Ethyl Ortho Silicate (TEOS) or Boron Phosphorus Silicon Glass (BPSG) oxide film, for example, can be used as the film thickness adjustment layer 102. A film deposition process that can be employed is, for example, a chemical vapor deposition (CVD) process. To focus on the reduction of the parasitic capacitance, an organic film having a low dielectric constant, such as Hydrogen silsesquioxane (HSQ), can be used as the film thickness adjustment layer 102 (Young's modulus: approximately 10 Gpa). Other examples are Methyl-silsesquioxane (MSQ) which is similarly an organic material having a low dielectric constant, and SiOF and SiOC which are inorganic materials having a low dielectric constant.

The film thickness adjustment layer may be thicker than the protective insulating layer, and the film thickness adjustment layer may be an insulating layer having Young's modulus smaller than 10 GPa.

The protective insulating layer 103 may be a film having Young's modulus equal to or larger than 100 GPa. More specifically, an example of the protective insulating layer is a densely formed silicon nitride film in which an N/Si stoichiometric mixture ratio is around 1.33. Other examples are oxides such as alumina and zirconia, ceramics such as diamond, hydroxides typified by hydroxyapatite, and carbides typified by SiC.

The Young's modulus is an indicator of a distortion generated by a stress. When different materials are used in films in proximity, their interfacial Young's modulus values should be as close to each other as possible to prevent either of the films from peeling off. Ti, Cu, and W, which are typical examples of a wiring material, have Young's modulus in the range of 100 to 400 GPa. Therefore, a film having Young's modulus included in or close to the numeral range may be used as an etching stopper film to avoid the peel-off problem.

When a semiconductor containing any of the Group IV elements, for example, silicon or germanium is used as the nanowire 107 and partially doped with an impurity, resistors, wirings, and diodes can be formed in the nanowire. The nanowire is applicable to an electronic wire detection device using ZnS or CdTe, and also applicable to an optical device using GaAs or GaN.

The electrode 109 maybe made of a metallic material, or a semiconductor doped with a high-concentration impurity in the volume of at least approximately 10¹⁷ per one cubic centimeter, for example, polysilicon mixed with dopant gas by LPCVD.

In any devices, inter-wiring parasitic capacitance adversely affects the time constant when these devices are driven. A general countermeasure to reduce the parasitic capacitance is to use a low dielectric film in layers of a device. However, a device including a three-dimensional structure or a vertical structure therein has a problem that such a three-dimensional structure often increases its parasitic capacitance as compared to a planar device.

Therefore, it is desirable in any devices including the three-dimensional or vertical structure therein to reduce the dielectric constant of an inter-wiring insulating film so that the parasitic capacitance is reduced. Thus, there is a strong demand for improving characteristics of a device having vertical nanowires as a structural device.

It is known that a dielectric constant film with a low density, such as HSQ, often has a rough molecular structure, failing to obtain a good adhesion to any other materials. For example, HSQ has a very poor adhesion that can be used in nanoimprint process as described in detail in Microelectronic Engineering 84, 12 (2007). In view of the reduction of the parasitic capacitances, it is desirable to use a low dielectric film alone for interlayer insulation. The use of such a film, however, involves a peel-off risk in the film-forming of wiring materials and patterning of wirings in subsequent steps.

According to the present exemplary embodiment, the protective insulating film which is mechanically strong and molecularly dense is interposed between the electrode and the film thickness adjustment layer having a low dielectric constant. The structural characteristic can prevent the electrode from peeling off due to poor adhesion. Conventionally, a film having a high mechanical strength is likely to have a high density and a high dielectric constant. The present exemplary embodiment, however, can adjust the thickness of the protective insulating layer to be just right for improving adhesion to the upper electrode wirings. Therefore, a large increase of the parasitic capacitance can be avoided as far as the film thickness adjustment layer is thick enough for the protective insulating layer.

A mechanically strong film is conventionally formed at low film-formation speeds. The formation of such a film in a large thickness may invite increase of a processing cost and an overload of machine time. Further, a large stress is generated in the film, possibly resulting in the occurrence of cracks and peel-off of the film from a substrate when the film is formed in a large thickness. Thus, there are a number of restrictions to increase the film thickness. The present exemplary embodiment can suitably provide a required film thickness because the protective insulating layer improves the adhesion, thereby reducing the risk of peel-off.

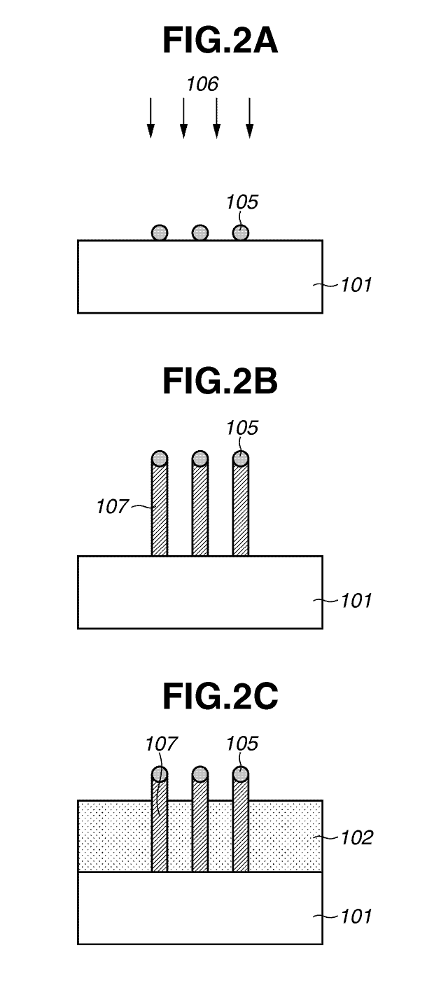

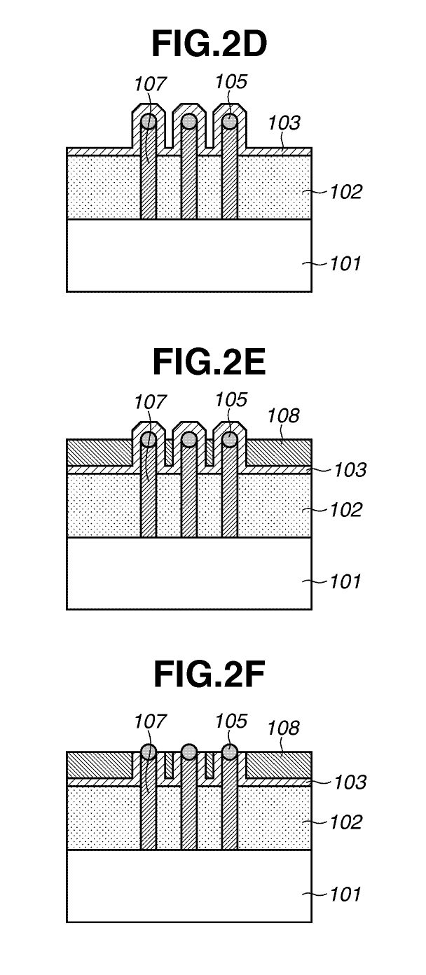

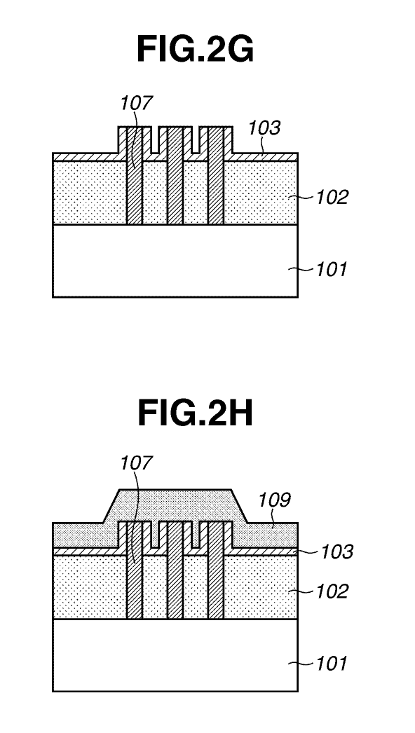

A production process for producing the semiconductor device according to the present exemplary embodiment is described below referring to FIGS. 2A to 2H. To start with, catalysts 105 are formed on the substrate 101 as illustrated in FIG. 2A. The substrate 101 may be a semiconductor made of, for example, silicon. Other than silicon, Ge is a usable material.

The catalyst 105 can be made of a material that can form eutectic with Si or Ge of the semiconductor, examples of which are Au, AlSi, Sn, Pb, Ni, Fe, and Ag. The catalyst 105 maybe provided in the form of catalytic fine particles or thin film. When the catalyst 105 is provided in the form of droplets, droplet diameters should be at most 200 nm. When an Au thin film having the thickness of 3 nm is used, Au particles having particle diameters of approximately 40 nm can be obtained in annealing under N₂ atmosphere at 370° C. for two minutes. When colloid is used, a solution including colloid dimensionally equal to the particle diameters of the nanowires to be grown is dropped and dried.

Next, a semiconductor material 106 that can form eutectic with the catalysts 105 is supplied to the substrate 101. Then, the substrate 101 is heated at a temperature at which the catalysts and the semiconductor can generate the eutectic reaction. In the case of growing silicon nanowires using catalytic Au, for example, the heating temperature is higher than the eutectic temperature, 363° C., and SiH₄ gas is supplied thereto.

The supply of SiH₄ gas makes the silicon dissolved in the catalytic Au, which becomes the molten eutectic droplets. As SiH₄ is then further supplied, Si in the molten droplets AuSi is supersaturated, and Si nanowires are grown. When GeH₄, for example, is used as the semiconductor material 106 in the step, Ge nanowires can be obtained.

As a result, the nanowires 107 are grown as illustrated in FIG. 2B. If Si is used for the substrate 101 so that Si nanowires are grown with Au being used as the catalyst, the nanowires are grown in the direction of <111> where the surface potential is lower as specifically described in Nano Letters, 5, 931 (2005). Thus, when Si (111) is used for the substrate 101, the nanowires can be formed substantially perpendicular to the substrate.

As illustrated in FIG. 2C, the film thickness adjustment layer 102 is formed after the nanowires are grown. A low dielectric film made of, for example, HSQ may be used as the film thickness adjustment layer 102 to effectively reduce the parasitic capacitance during a device operation. An MSQ film is also usable. The film-forming process mostly adopted is spin coating, wherein number of and time for sample rotations during the film coating are regulated so that edges of the nanowires are exposed.

Then, the protective insulating layer 103 is formed on the film thickness adjustment layer 102 as illustrated in FIG. 2D. An example of the protective insulating layer 103 is a densely formed silicon nitride film having the N/Si stoichiometric mixture ratio of around 1.33 and having a high mechanical strength as compared to the film thickness adjustment layer 102. The protective insulating layer 103 is suitably formed by CVD.

The protective insulating layer 103 has Young's modulus equal to or larger than 200 GPa and can exert a better adhesion to the other materials than the low dielectric film used as the film thickness adjustment layer. Further, the protective insulating layer 103 having such a remarkable strength can avoid possible exposure of the low dielectric film easily subject to mechanical and chemical processes during wash and patterning of wirings formed on upper ends of the nanowires in subsequent steps as far as processing conditions are properly set. This advantage is expected to lead to steady production and supply of a device.

Then, an etching protective layer 108 is formed as illustrated in FIG. 2E. More specifically, a polyimide film is suitably formed by spin coating. A requirement in the formation of the polyimide film may be to adjust its film thickness so that edges of the nanowires coated with the protective insulating layer are exposed after coating and baking. The film thickness can be adjusted by regulating number of and time for sample rotations during the film coating.

If the edges of the nanowires after the film coating remain unexposed, an etch back process by using, for example, RIE etching, can process the polyimide so that the edges of the nanowires are exposed as far as the surface after film coating is flat.

Then, the protective insulating layer 103 is selectively removed as illustrated in FIG. 2F. When a silicon nitride film is used as the protective insulating layer 103, for example, etching by using CF₄-based gas is suitably used for the removal.

The catalysts 105 are then selectively removed as illustrated in FIG. 2G. When the catalysts 105 are made of Au, for example, a potassium iodide (KI) solution can be used to selectively remove the catalysts 105. The removal of the catalysts 105 enables a direct contact between the nanowires 107 and the electrode 109 as described below. The other advantages of the removal of the catalysts 105 are such that contact resistance at contact points can be controlled, and such a metallic catalyst that often forms an impurity level in the semiconductor can be removed.

Finally, the electrode 109 is formed so that the exposed end surfaces of the nanowires 107 are coated therewith as illustrated in FIG. 2H. A material of the electrode may be metal or a semiconductor having such an impurity concentration that a volume of carriers large enough for the nanowires 107 to effectuate the device operation are included. For example, polysilicon with dopant gas mixed therein by LPCVD is also a usable material. In the case of metal, any metal having a suitable work function can be used depending on a device design according to Fermi level of the semiconductor constituting the nanowire. In the case of the semiconductor, a film having a suitable Fermi level can be formed depending on the type and concentration of the dopant gas, so that contacts suitable for the device design can be obtained.

As a result of the processing steps illustrated in FIGS. 2A to 2H, the semiconductor device according to the present exemplary embodiment can be obtained.

As described so far based according to the exemplary embodiment, the present invention can provide a semiconductor device in which parasitic capacitance is reduced.

The present invention is advantageous for improving characteristics of a semiconductor device provided with vertically formed nanowires, and particularly advantageous for improving time constant in a high-speed operation.

While the present invention has been described with reference to exemplary embodiments, it is to be understood that the invention is not limited to the discussed exemplary embodiments. The scope of the following claims is to be accorded the broadest interpretation so as to encompass all modifications, equivalent structures, and functions.

This application claims priority from Japanese Patent Application No. 2010-102693 filed Apr. 27, 2010, which is hereby incorporated by reference herein in its entirety.

What is claimed is:

1. A semiconductor device having:
a multilayered structure in which multiple layers are stacked on a planar main surface of an electrically conductive substrate in the order of a film thickness adjustment layer, a protective insulating layer, and an electrode, wherein
nanowires penetrate through the film thickness adjustment layer and the protective insulating layer to electrically connect the electrically conductive substrate and the electrode to each other.

2. The semiconductor device according to claim 1, wherein the nanowires are formed substantially perpendicular to the planar surface of the electrically conductive substrate.

3. The semiconductor device according to claim 1, wherein the nanowires each have a diameter in the range of at least 1 nm to at most 200 nm.

4. The semiconductor device according to claim 1, wherein the nanowires contain one of a Group IV element, a compound including a Group III element and a Group V element, and a compound including a Group II element and a Group VI element by at least 90% by weight.

5. The semiconductor device according to claim 4, wherein the Group IV element is Si, Ge or Si, Ge, C.

6. The semiconductor device according to claim 4, wherein the compound including the Group III element and the Group V element is a compound in which one of Ga, Al, and In of the Group III element is included or at least two of these substances are combined, and N, P, As, Sb, or Bi is included as the Group V element.

7. The semiconductor device according to claim 4, wherein the compound including the Group II element and the Group VI element is a compound in which Zn or Cd is included as the Group II element and O, Se, or Te is included as the Group VI element.

8. The semiconductor device according to claim 1, wherein the protective insulating layer has Young's modulus equal to or larger than 100 GPa.

9. The semiconductor device according to claim 1, wherein the film thickness adjustment layer is thicker than the protective insulating layer, and the film thickness adjustment layer is an insulating layer having Young's modulus smaller than 100 GPa.

10. The semiconductor device according to claim 1, wherein the electrode is made of metal, a semiconductor doped with an impurity, or silicide.

11. The semiconductor device according to claim 10, wherein the impurity includes at least any one of B, P, and As.

12. The semiconductor device according to claim 10, wherein the silicide includes a combination of Si and any of Ti, Zr, Hf, V, Nb, Ta, Cr, W, Mn, Tc, Re, Fe, Ru, Os, Co, Rh, Ir, Ni, Pd, Pt, and Al.
